(19) United States
(12) Patent Application Publication
(10) Pub. No.: US 2021/0066921 A1
(43) Pub. Date: Mar. 4, 2021

(54) METHOD FOR DETECTING THE INPUT CHANNEL CONFIGURATION OF A MULTI-CHANNEL INVERTER

(71) Applicant: ABB Schweiz AG, Baden (CH)

(72) Inventors: Silvio Scaletti, Civitella in Val Di Chiana (AR) (IT); Alessandro Guerriero, Paglieta (CH) (IT)

(21) Appl. No.: 16/959,455

(22) PCT Filed: Dec. 21, 2018
(86) PCT No.: PCT/EP2018/086602

§ 371 Date: Jul. 1, 2020

(30) Foreign Application Priority Data
Jan. 5, 2018 (EP) 18150418.4

(51) Int. Cl. H02J 3/38; H02S 40/32; H02M 7/493; G01R 31/40; H02J 1/10

(52) U.S. Cl. CPC H02J 3/381; H02S 40/32; H02J 2300/24; G01R 31/40; H02J 1/102; H02M 7/493

(57) ABSTRACT

A method for detecting an input channel configuration of a multi-channel inverter having a plurality of input channels. Each input channel is electrically connected with a corresponding power converter and, upon an operative installation of said multi-channel inverter, being operatively associated to a DC electric power source. The method includes the following: selecting a reference input channel among the input channels; controlling the power converters to allow an input current higher than a current threshold to flow along the reference input channel and to allow input currents lower than the current threshold to flow along one or more remaining input channels different from the reference input channel; acquiring detection data indicative of input voltages of the input channels; performing a comparison between the input voltages of the input channels; executing a determination procedure to determine a configuration status of the input channels based on a behaviour of the input voltages of the remaining input channels with respect to the input voltage of the reference channel.

The present invention relates to a method for detecting the input channel configuration of a multi-channel inverter.

As is known, a multi-channel inverter comprises an input section and an output section adapted to receive DC electric power from a DC electric system and provide AC electric power to an AC electric system, respectively.

As an example, in photovoltaic installations, a multi-channel inverter may comprise the input section electrically connected with a photovoltaic panel or a photovoltaic string and the output section electrically connected with an electric power distribution grid.

In a multi-channel inverter, the above-mentioned input section includes a plurality of input channels, each of which is electrically connected with a corresponding power converter (e.g. a DC/DC power converter) and, in operation, with a corresponding DC electric power source.

In many applications, e.g. in photovoltaic plants, multi-channel inverters may have some input channels electrically connected in parallel with a same DC source and other input channels operating independently, i.e. singularly connected with a corresponding DC source.

For this reason, during the commissioning phase, normally, the control unit of a multi-channel inverter has to be properly configured to take into account the physical connection status of the input channels and ensure a proper operation of the inverter.

In currently available installations, the above-mentioned configuration operation entails the intervention of specialized personnel.

As an example, in some cases, an operator can carry out such a configuration operation by manually setting a dip switch of the control unit of the inverter.

As a further example, in other cases, an operator can provide the control unit with configuration information indicative of the input channel configuration of the inverter through a HMI (e.g. a touch display) or by downloading a suitable configuration file.

As it is easy to understand, the need for carrying out the above-mentioned configuration operations entails a remarkable increase of the commission time and costs to put the photovoltaic inverter in condition to operate.

Nowadays, there is a relevant market demand for having multi-channel inverters that can be installed on the field with lowered (virtually null) commissioning time and costs.

In the state of the art, it is therefore quite felt the need for solutions overcoming or mitigating the above-illustrated drawbacks of the state of the art.

The present invention intends to respond to this need by providing a method for detecting the input channel configuration of a multi-channel inverter, according to the following claim 1 and the related dependent claims.

In a general definition, the method, according to the invention, comprises the following steps:
a) selecting a reference input channel among said input channels;
b) controlling power converters electrically connected with said input channels to allow an input current higher than a current threshold to flow along said reference input channel and to allow input currents lower than said current threshold to flow along one or more remaining input channels different from said reference input channel;
c) acquiring detection data indicative of input voltages of said input channels;
d) performing a comparison between the input voltages of said input channels;
e) executing a determination procedure to determine a configuration status of said input channels based on a behavior of the input voltages of said remaining input channels with respect to the input voltage of said reference channel.

Preferably, said step b) of controlling said power converters comprises activating the power converter corresponding to said reference input channel and deactivating or maintaining deactivated the power converters corresponding to said remaining input channels.

According to an aspect of the invention, said step d) of performing a comparison between the input voltages of said input channels comprises checking whether the input voltages of said remaining input channels behave as the input voltage of said reference input channel.

According to an aspect of the invention, said determination procedure comprises the following step:
e.1) if the input voltages of said remaining input channels do not decrease as the input voltage at said reference input channel, determining that said reference input channel is an independent input channel.

According to an aspect of the invention, said determination procedure further comprises the following steps:
e.2) if there is a single remaining input channel, determining that said remaining input channel is an independent input channel; or
e.3) if there is a plurality of remaining input channels, repeating said steps a), b), c), d), e) for said remaining input channels.

According to an aspect of the invention, said determination procedure comprises the following step:
e.4) if the input voltages of one or more first remaining input channels decrease as the input voltage at said reference input channel, determining that said reference input channel and said one or more first remaining input channels are parallel input channels.

According to an aspect of the invention, if the input voltages of one or more second remaining input channels, different from said first remaining input channels, do not decrease as the input voltage of said reference input channel said determination procedure comprises the following steps:
e.5) if said second remaining channels include a single second remaining input channel, determining that said remaining input channel is an independent input channel; or
e.6) if said second remaining channels include a plurality of second remaining input channels, repeating said steps a), b), c), d), e) for said second remaining input channels.

Preferably, the method, according to the invention, comprises the step f) of storing configuration information indicative of the configuration status determined for said input channels.

In a further aspect, the present invention relates to a multi-channel inverter, according to the following claim 9 and the related dependent claims.

Further features and advantages of the present invention will be apparent in the following description of non-limitative embodiments with reference to the figures in the accompanying drawings, in which:

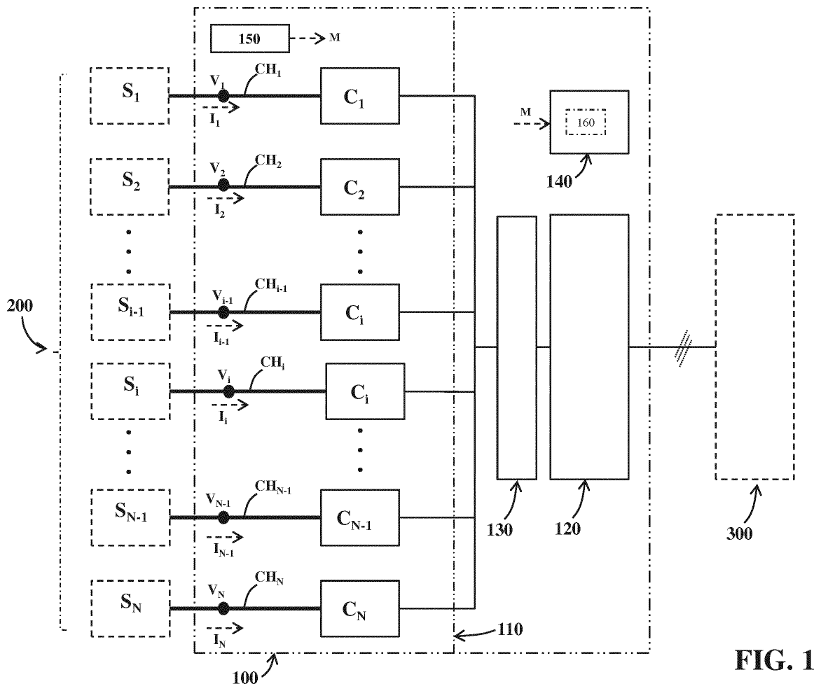

FIG. 1 shows a schematic block diagram of a photovoltaic inverter implementing the method according to the present invention;

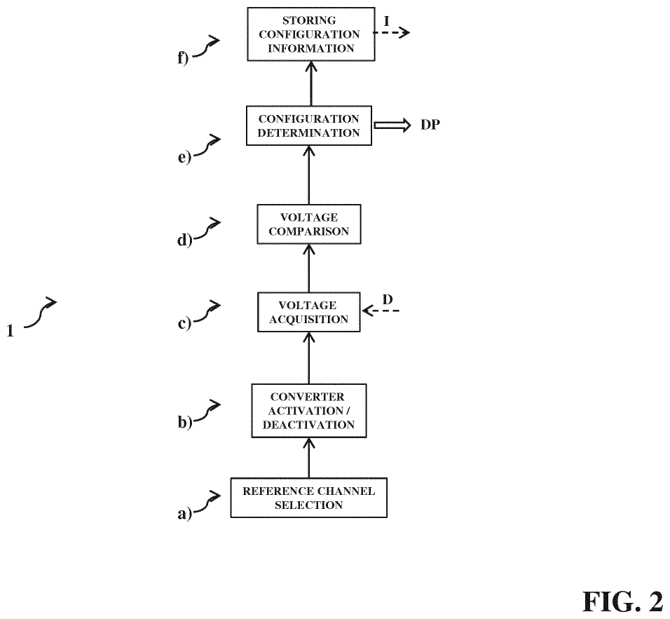

FIG. 2 shows a schematic block diagram describing the steps of method according to the present invention;

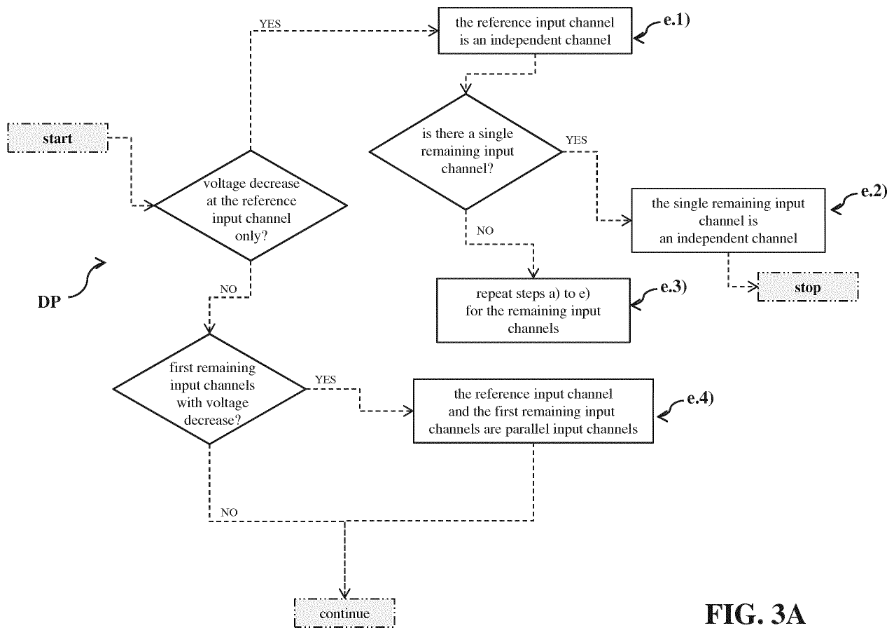

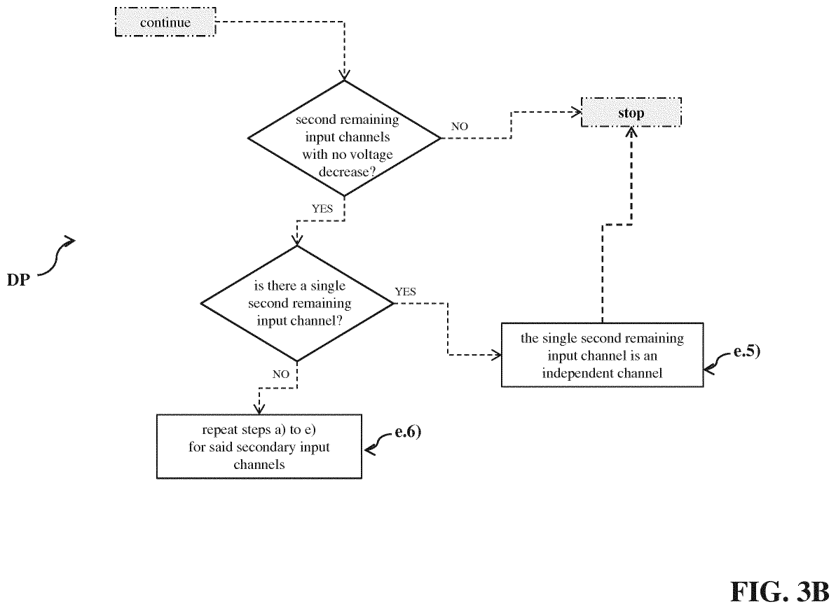

FIGS. 3A-3B show a schematic block diagram describing in details a determination procedure carried out by the method according to the present invention;

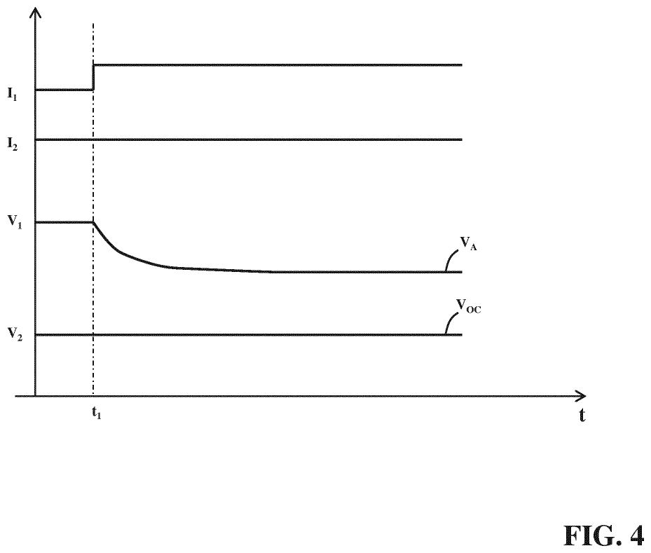

FIGS. 4-9 schematically illustrate some examples of implementation of the method, according to the invention, in a multi-channel inverter;

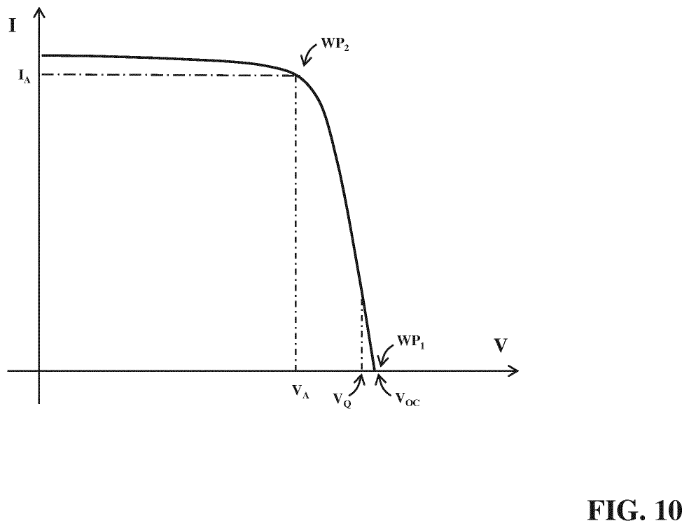

FIG. 10 schematically illustrates an example of operational characteristic curve of a photovoltaic source.

Referring to the cited figures, the present invention relates to a method for detecting the input channel configuration of a multi-channel inverter 100.

The multi-channel inverter 100 is particularly adapted for use in photovoltaic installations and, in the following, it will be described with particular reference to these applications without intending to limit the scope of the invention. In fact, the multi-channels inverter 100 may be conveniently used in low-voltage installations of different types, such as those including batteries, capacitor banks, and the like, as DC electric power sources.

For the sake of clarity, it is specified that the term “low voltage” refers to operating voltages lower than 1 kV AC and 1.5 kV DC.

With particular reference to FIG. 1, the inverter 100 comprises an input section 110 that, in operation, is intended to be electrically connected with a DC electric system 200 adapted to provide DC electric power in output.

The input section 110 comprises a plurality of input channels CH₁, CH₂, . . . , CHᵢ₋₁, CHᵢ, . . . , CH_{N-1}, CH_{N}, each of which is electrically connected with a DC electric power source S₁, S₂, . . . , Sᵢ₋₁, Sᵢ, . . . , S_{N-1}, S_{N} when the inverter 100 is installed on the field.

The DC sources S₁, . . . , S_{N} may include photovoltaic panels or strings, batteries, capacitor banks or other electric and/or electronic apparatuses providing DC electric power in output (e.g. photovoltaic panel optimizing apparatuses).

The inverter 100 may be operatively coupled to DC sources S₁, . . . , S_{N} of a same type (e.g. all including photovoltaic panels or strings) or of different types (e.g. including photovoltaic panels or strings and/or batteries and/or capacitor banks and/or other apparatuses as illustrated above).

The input section 110 comprises a plurality of power converters C₁, C₂, . . . , Cᵢ₋₁, Cᵢ, . . . , C_{N-1}, C_{N}, each of which may comprise, for example, one or more DC/DC converters.

Conveniently, each power converter C₁, . . . , C_{N} is electrically connected with a corresponding input channel CH₁, . . . , CH_{N}.

The inverter 100 further comprises an output section 120 intended, in operation, to be electrically connected with an AC electric system 300, preferably an electric power distribution grid, e.g. of single-phase or multi-phase type.

The output section 120 may comprise, for example, one or more further power converters, e.g. one or more AC/AC converters.

Conveniently, the inverter 100 may comprise a coupling section 130 to electrically connect the input section 110 and the output section 120.

The coupling section 130 may comprise, for example, one or more capacitor banks (DC-Link stage) electrically connected in parallel between the output terminals of the input section 110 and the input terminals of the output section 120.

Conveniently, the inverter 100 comprises control means 140 to control its functionalities, in particular the operation of the input and output sections 110, 120.

In an industrial implementation of the inverter 100, the control means 140 may comprise one or more control units arranged on-board the inverter.

Preferably, the control means 140 include data processing resources 160 to carry out their functionalities.

If industrially implemented in analog manner, the data processing resources 160 may comprise suitably arranged electronic circuits of analog type.

If industrially implemented in a digital manner, the data processing resources 160 may comprise one computerized units (e.g. DSPs or microprocessors) configured to execute sets of software instructions stored or storable in a medium.

As a further alternative, the data processing resources 160 may comprise integrated circuits or other electronic arrangements (e.g. FPGAs, SoC, and the like) capable of processing analog and/or digital signals.

Preferably, the control means 140 are configured to control the power converters C₁, . . . , C_{N} of the input section 110 operatively associated to the input channels CH₁, . . . , CH_{N}.

As an example, the control means 140 are conveniently configured to activate or deactivate the above-mentioned power converters and/or operate them according to given working functions.

It is important to put in clear evidence that the control means 140 can control the input currents I₁, I₂, . . . , Iᵢ₋₁, Iᵢ, . . . , I_{N-1}, I_{N} flowing along each input channel CH₁, . . . , CH_{N} by suitably controlling the corresponding power converter C₁, . . . , C_{N}.

Supposing that the inverter 100 is operatively coupled to photovoltaic sources S₁, . . . , S_{N} at the input channels CH₁, . . . , CH_{N}, when a generic input channel CHᵢ of the inverter 100 is electrically connected with a photovoltaic source Sᵢ, the input voltage Vᵢ of said input channel typically follows the operational characteristic curve of said photovoltaic source, an example of which is schematically shown in FIG. 10.

As it is possible to observe, said operational characteristic curve has a monotone trend, which means that, in operation, a single voltage value at said input channel univocally corresponds to a given current value flowing along said input channel.

When no input current flows (Iᵢ=0 a part from said leakage currents) along said generic input channel CHᵢ, the photovoltaic source Sᵢ operates at the working point WP₁. In this case, the input voltage Vᵢ of the input channel CHᵢ is Vᵢ=V_{OC}, where V_{OC} is a no-load voltage value. When an input current Iᵢ flows along said generic input channel CHᵢ, the photovoltaic source Sᵢ operates at a different working point WP₂. In this case, the input voltage Vᵢ of the input channel CHᵢ decreases and takes a value Vᵢ=V_{A}, where V_{A} is a unique voltage value corresponding to the working point WP₂.

In operation, the position of the working point WP₂ (and therefore the corresponding voltage value V_{A}) depends on the current value I_{A} imposed by the power converter Cᵢ operatively associated to the generic input channel CHᵢ.

The value I_{A} of the current flowing along the input channel CHᵢ depends, in turn, on the kind of regulation, for example a MPPT (Maximum Power Point Tracking) regulation, constant power regulation, or the like, carried out by said power converter Cᵢ.

Of course, the above considerations are valid mutatis mutandis for other types of above-mentioned DC electric power sources depending on their operational characteristic curves.

In order to control the above-mentioned power converters, the control means 140 may be configured to provide suitable control signals, control variables, reference currents, reference voltages, control flags and the like.

Preferably, the inverter 100 comprises sensing means 150 adapted to provide the control means 140 with detection signals M indicative of the input voltages V₁, V₂, . . . , Vᵢ₋₁, Vᵢ, . . . , V_{N-1}, V_{N} of the input channels CH₁, . . . , CH_{N} (more precisely at the input terminals of said input channels).

In general, the DC electric system 200 (e.g. the DC sources S₁, . . . , S_{N} thereof), the AC electric system 300 and most of the components of the input section 110 (e.g. the input channel channels CH₁, . . . , CH_{N} and the corresponding converters C₁, . . . , C_{N} thereof), of the output section 120 and, possibly, of the coupling section 130 as well as the sensing means 150 may be of known type and will not be here described in further details for the sake of brevity.

With particular reference to FIGS. 2, 3A, 3B, and 9, the method 1, according to the invention, is now described in details.

In general terms, the method 1 is aimed at detecting the input channel configuration of the multi-channel inverter 100.

For the sake of clarity, it is specified that the locution “detecting an input channel configuration of the multi-channel inverter” means the detection of the physical connection arrangement of the input channels of said inverter with a DC electric source, in practice detecting whether the input channels of said inverter are electrically connected in parallel with a same DC source or are singularly connected with a corresponding DC source.

In the following, for the sake of brevity, an input channel singularly connected with a corresponding DC electric power source is defined as “independent input channel” whereas input channels electrically connected in parallel with a same DC electric power source are defined as “parallel input channels”.

The method 1 comprises a step a) of selecting a reference input channel (e.g. the input CH₁) among the input channels CH₁, . . . , CH_{N} of the inverter 100.

In a practical implementation of the invention, the reference input channel CH₁ may be selected in a group of available input channels according to a predefined sorting order or according to a random sorting order.

As it will better emerge from the following, such a group of available input channels initially include all the input channels of the inverter 100. However, said group of available input channels comprises only selected input channels of the inverter 100 (in particular those still having an undetermined configuration status), when the method 1 is recursively repeated.

Upon carrying out the above-illustrated step a), the method 1 comprises a step b) of controlling the power converters C₁, . . . , C_{N} to allow an input current I₁ higher than a current threshold I_{TH} to flow along the reference input channel CH₁ and to allow input currents I₂, . . . , I_{N} lower than said current threshold to flow along one or more remaining input channels CH₂, . . . , CH_{N} different from the reference input channel CH₁.

In a preferred embodiment of the invention, the above-mentioned step b) comprises activating the power converter C₁ corresponding to the selected reference input channel CH₁ and deactivating the power converters C₂, . . . , C_{N} corresponding to the remaining input channels CH₂, . . . , CH_{N}.

Such preferred embodiment of the invention corresponds to the case in which the current threshold I_{TH} is set as I_{TH}=0 A.

However, other embodiments of the invention may provide for activating all the power converters C₁, . . . , C_{N} and controlling these latter in such a way that, at a given check instant, the input current I₁ flowing along the reference input channel CH₁ is higher than the current threshold I_{TH} whereas the input currents I₂, . . . , I_{N} flowing along the remaining input channels CH₂, . . . , CH_{N} is lower than said current threshold.

To this aim, for example, the power converters C₁, . . . , C_{N} may be controlled in such a way that, at a given check instant, an input current I₁ having a higher growth rate is allowed to flow along the reference input channel CH₁ and input currents I₂, . . . , I_{N} having lower grow rates are allowed to flow along the remaining input channels CH₂, . . . , CH_{N}.

According to other embodiments (not shown), both the above-mentioned solutions or additional equivalent solutions may be implemented.

Upon carrying out the above-illustrated step b), the method 1 comprises a step c) of acquiring detection data D indicative of the input voltages V₁, . . . , V_{N} of the input channels CH₁, . . . , CH_{N} of the inverter 100 (more precisely at the input terminals of said input channels).

In a practical implementation of the invention, the detection data D may be acquired by suitably processing the detection signals M received from the above-mentioned sensing means 150.

Upon carrying out the above-illustrated step c), the method 1 comprises a step d) of performing a comparison between the input voltage V₁ of the reference channel CH₁ and each of the input voltages V₂, . . . , V_{N} of the remaining input channels CH₂, . . . , CH_{N} based on the detection data D so acquired.

Preferably, the above-mentioned step d) comprises checking whether the input voltages V₂, . . . , V_{N} of the remaining input channels CH₂, . . . , CH_{N} behave (more particularly decrease) as the input voltage V₁ of the reference input channel CH₁.

In a practical implementation of the invention, at a given check instant, the voltage differences between each input voltage V₂, . . . , V_{N} of the remaining input channels CH₂, . . . , CH_{N} and the input voltage V₁ of the reference channel CH₁ may be calculated and compared with predefined threshold values to determine whether the compared input voltages behave in a similar manner or in a different manner.

As an example, the voltages V₁, V₂ of the input channels CH₁, CH₂ can be determined as behaving in a same or different manner depending on whether the following relation is true or false at a given check instant:

ΔV₂₁=|V₂−V₁|<V_{TH}

where V_{TH} is a predefined threshold value.

Upon carrying out the above-illustrated step d), the method 1 comprises a step e) of carrying out a determination procedure DP to determine the configuration status of the input channels CH₁, CH₂, . . . , CH_{N} based on behavior of the input voltages V₂, . . . , V_{N} of the remaining input channels CH₂, . . . , CH_{N} with respect to the input voltage V₁ of the selected reference channel CH₁.

In general terms, the determination procedure DP allows determining the input channel configuration of the inverter 100 properly observing the behavior of the input voltages at said input channels (more precisely at the input terminals of said input channels).

At a given check instant, upon the execution of the step b) of the method 1), a certain input current I₁ flows along the reference input channel CH₁ whereas null or lower input currents I₂, . . . , I_{N} flow along the remaining input channels CH₂, . . . , CH_{N}.

Referring to FIG. 10, this means that, upon the execution of the step b) of the method 1, the DC source S₁ electrically connected with the reference input channel CH₁ operates at a working point WP₂, at which the input voltage V₁ of the reference input channel CH₁ decreases to the value V₁=V_{A}.

As a consequence, the input voltage of possible remaining input channels electrically connected in parallel with the reference input channel CH₁ will follow the input voltage V₁ of the reference input channel CH₁ thereby decreasing from its no-load voltage value V_{OC} to the value V₁=V_{A}.

On the other hand, the input voltage of possible remaining input channels not electrically connected in parallel with the reference input channel CH₁ will stably remain at its no-load voltage value V_{OC} or will decrease to a value V_{Q} higher than V₁=V_{A} (e.g. in a neighborhood of the voltage value V_{OC}) as null currents or currents lower than the current I₁=I_{A} are allowed to flow along said input channels.

The physical connection arrangement of each input channel CH₁, . . . , CH_{N} can thus be determined by properly observing the behavior of the input voltages V₂, . . . , V_{N} of the remaining input channels CH₂, . . . , CH_{N} in relation to the input voltage V₁ of the reference channel CH₁.

More particularly, the configuration status of each input channel CH₁, . . . , CH_{N} can be determined by properly checking whether the input voltages V₂, . . . , V_{N} of the remaining input channels CH₂, . . . , CH_{N} decrease as the input voltage V₁ of the reference input channel CH₁.

As illustrated above, the voltage differences between each of the input voltages V₂, . . . , V_{N} of the remaining input channels CH₂, . . . , CH_{N} and the input voltage V₁ of the reference channel CH₁ may be calculated and compared with predefined threshold values to carry out such a checking activity.

Preferably, the above-mentioned step e) of the method 1 comprises a structured determination procedure DP to determine the input channel configuration of the inverter 100 on the basis of the of the detection data D (FIGS. 3A-3B).

Initially, the method 1 provides for considering the preliminary event, according to which only the input voltage V₁ of the reference input channel CH₁ decreases upon the execution of the step b) of the method 1.

If such a preliminary event is verified, the reference input channel CH₁ cannot be electrically connected in parallel with any remaining input channel CH₂, . . . , CH_{N} of the inverter 100 as none of the input voltages V₂, . . . , V_{N} of said remaining input channels behaves (i.e. decreases) as the input voltage V₁ of the reference input channel CH₁, upon the execution of the step b) of the method 1.

This means that the reference input channel CH₁ is an independent channel.

In view of the above, the determination procedure DP preferably comprises a step e.1) of determining that the reference input channel CH₁ is an independent channel, if the input voltages V₂, . . . , V_{N} of the remaining input channels CH₂, . . . , CH_{N} do not decrease as the input voltage V₁ of the reference input channel CH₁.

In other words, according to the step e.1), the reference input channel CH₁ is determined as an independent channel, if none of the input voltages V₂, . . . , V_{N} of the remaining input channels CH₂, . . . , CH_{N} decreases as the input voltage V₁ of the reference input channel CH₁ upon the execution of the step b) of the method 1.

At this level of the determination process, the subsequent steps of the determination procedure DP depend on whether the remaining input channels CH₂, . . . , CH_{N} include a single input channel or multiple input channels.

If a single remaining input channel (e.g. the step CH₂) is present, this latter is necessarily an independent channel.

In this case, in fact, the inverter 100 would necessarily include two input channels CH₁, CH₂ only, one of which (the reference input channel CH₁) has already been determined as an independent channel.

For this reason, upon the execution of the above mentioned step e.1), the determination procedure DP preferably comprises the following step e.2): if there is a single remaining input channel, determining that said single remaining input channel is an independent input channel.

Upon the execution of the step e.2), the determination procedure DP is terminated as it has been possible to determine the configuration of all the input channels (e.g. CH₁ and CH₂) of the inverter 100.

If the remaining input channels CH₂, . . . , CH_{N} include multiple input channels, no determination can be taken on said remaining input channels, even if the reference input channel CH₁ has already been determined an independent input channel.

In fact, since the power converters C₂, . . . , C_{N} operatively associated to the remaining input channels CH₂, . . . , CH_{N} are deactivated or low currents flow said remaining input channels, the input voltages V₂, . . . , V_{N} of the remaining input channels CH₂, . . . , CH_{N} stably remain at their no-load voltage values or take values higher than the input voltage V₁ and no information on their configuration can be derived from such a behavior. For example, they may be all configured as independent channels or some of them may be electrically connected in parallel with a same DC source.

For this reason, upon the execution of the above mentioned step e.1), alternatively with respect to the above-mentioned step e.2), the determination procedure DP preferably comprises the step e.3) of repeating the above mentioned steps a), b), c), d), e) for the remaining input channels CH₂, . . . , CH_{N}, if there is a plurality of remaining input channels CH₂, . . . , CH_{N}.

In practice, in this case, the method 1 is recursively executed for a new group of available input channels, which includes all the multiple remaining input channels CH₂, . . . , CH_{N} and which does not include the previously selected reference input channel CH₁.

Obviously, during such a recursive execution of the method 1, a new reference input channel and new remaining input channels have to be selected among the remaining input channels CH₂, . . . , CH_{N} in accordance with the step a) of the method 1.

If the input voltages of one or more first remaining input channels CH₂, . . . , CHᵢ₋₁ of the inverter 100 decrease as the input voltage V₁ of the reference input channel CH₁, it means that the reference input channel CH₁ and said first remaining input channels are electrically connected in parallel with a same DC source (formed by the coincident DC sources S₂, . . . , Sᵢ₋₁) as their input voltages V₁, V₂, . . . , Vᵢ₋₁ behave (i.e. decrease) in a similar way upon the execution of the step b) of the method 1.

For this reason, the determination procedure DP preferably comprises the following step e.4): if the input voltages V₂, . . . , Vᵢ₋₁ of one or more first remaining input channels CH₂, . . . , CHᵢ₋₁ decrease as the input voltage V₁ of the reference input channel CH₁, determining that the reference input channel CH₁ and the first remaining input channels CH₂, . . . , CHᵢ₋₁ are parallel input channels.

At this level of the determination process, as logic alternatives to the above-described condition, the following possible events may occur:
there are no first remaining input channels with input voltages decreasing as the input voltage of the reference input channel; or
the above-mentioned first remaining channels do not include all the remaining input channels.

In both these cases, it is necessary to check whether there are second remaining input channels (e.g. the input channels CHᵢ, . . . , CH_{N}) different from the first remaining input channels CH₂, . . . , CHᵢ₋₁ having input voltages Vᵢ, . . . , V_{N} that do not decrease as the input voltage V₁ of the reference input channel CH₁.

If there are no second remaining input channels CHᵢ, . . . , CH_{N}, the input voltage of which does not decrease as the input voltage V₁ of the reference input channel CH₁, the determination procedure DP is terminated.

Such an event, in fact, would necessarily imply that the above-mentioned first remaining channels CH₂, . . . , CHᵢ₋₁ (the configuration of which is already determined) include all the input channels of the inverter 100 different from the reference input channel CH₁ (in practice all the above-mentioned remaining input channels of the inverter 100).

If there are second remaining input channels CHᵢ, . . . , CH_{N}, the input voltage of which does not decrease as the input voltage V₁ of the reference input channel CH₁, the subsequent determination steps of the determination procedure DP depend on whether said second remaining input channels include a single input channel or multiple input channels.

If the second remaining input channels of the inverter 100 include a single input channel, this latter is necessarily an independent channel.

In this case, in fact, such a second remaining input channel would be the only channel with an input voltage that does not decrease as the input voltages of the other input channels (i.e. the reference input channel and the first remaining input channel) of the inverter 100.

For this reason, upon the execution of the above mentioned step e.4), the determination procedure DP preferably comprises the following step e.5): if there is a single second remaining input channel, determining that said single second remaining input channel is an independent input channel.

Upon the execution of the step e.5), the determination procedure DP is virtually terminated as it has been possible to determine the configuration of all the input channels of the inverter 100.

If the second remaining input channels of the inverter 100 include multiple input channels, no determination can be taken on the configuration status of said input channels.

In fact, upon the execution of the step b) of the method 1, these second remaining input channels stably remain at their no-load voltage values or take values higher than the input voltage V₁ and no information on their configuration can be derived from such a behavior.

For this reason, upon the execution of the above mentioned step e.5), the determination procedure DP preferably comprises the step e.6): if there is a plurality of second remaining input channels, repeating the above mentioned steps a), b), c), d), e) for said second remaining input channels.

In practice, in this case, the method is recursively executed for a new group of available input channels, which include the second remaining input channels CHᵢ, . . . , CH_{N} only and which does not include the reference input channel CH₁ and the first remaining input channels CH₂, . . . , CHᵢ₋₁.

Obviously, during such a new recursive execution of the method 1, a new reference input channel and new remaining input channels have to be selected among said second remaining input channels CHᵢ, . . . , CH_{N} in accordance with the step a) of the method 1.

Referring now to FIGS. 4-9, some examples of implementation of the method 1 to better explain the determination process, which is implemented by the determination procedure DP, are described.

For the sake of simplicity, the following examples #1 to #5 (FIGS. 4-8) refer to the preferred embodiment in which, at the step b) of the method 1, the power converter corresponding to the reference input channel is activated whereas the one or more power converters operatively associated to one or more remaining input channels are maintained deactivated.

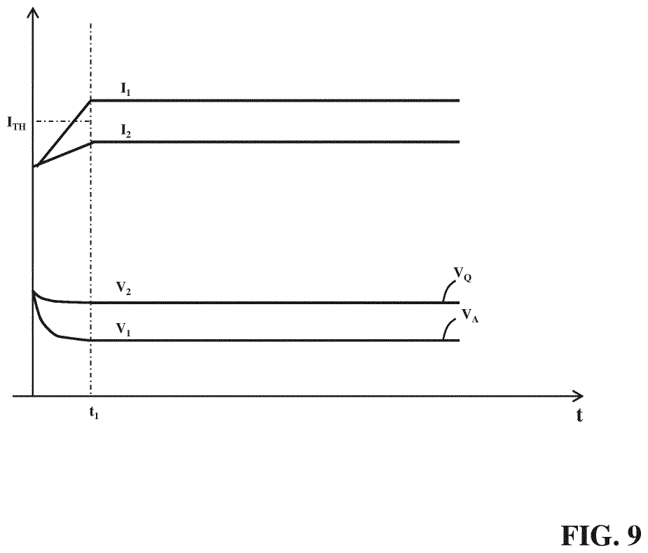

Example #6 (FIG. 9) instead refers to the more general case in which, at the step b) of the method 1, the power converters C₁, . . . , C_{N} are controlled in such a way the input current flowing along the reference input channel is set higher than a current threshold I_{TH} and the input currents flowing along the remaining input channels are set lower than said current threshold.

### EXAMPLE #1

The inverter 100 is supposed to have two input channels CH₁, CH₂ electrically connected with corresponding DC sources S₁, S₂ and corresponding power converters C₁, C₂ that are supposed to be initially deactivated.

According to the step a) of the method 1, the input channel CH₁ is selected as a reference input channel. As a consequence, the input channel CH₂ represents the remaining input channel of the inverter 100 as defined above.

According to the step b) of the method 1, at a given check instant t₁, the power converter C₁ corresponding to the reference input channel CH₁ is activated whereas the power converter C₂ operatively associated to the remaining input channel CH₂ is maintained deactivated.

According to the steps c)-d) of the method 1, detection data D related to the input voltages V₁, V₂ of the input channels CH₁, CH₂ are acquired and compared.

As it is possible to observe from FIG. 4, following the activation of the power converter C₁ at the check instant t₁, the input voltage V₁ of the reference input channel CH₁ starts naturally decreasing towards a given operating value V_{A}. This latter value depends on the current regulation performed by the power converter C₁ (FIG. 10). Instead, the input voltage V₂ of the remaining input channel CH₂ stably remains at its no-load value V_{OC}.

According to the steps e.1)-e.2) of the determination procedure DP, both the input channels CH₁, CH₂ are determined as independent input channels.

The determination of the configuration status of the input channels of the inverter 100 is completed.

### EXAMPLE #2

In this example, the inverter 100 is arranged as in the example #1, i.e. it comprises two input channels CH₁, CH₂.

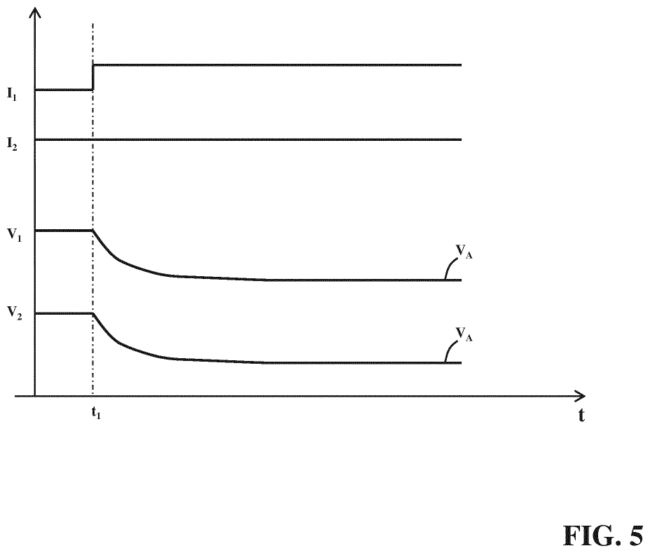

As it is possible to observe from FIG. 5, differently from the previous example, following the activation of the power converter C₁ at the check instant t₁, the input voltage V₂ of the remaining input channel CH₂ behaves as the input voltage V₁ of the reference input channel CH₁, i.e. it starts decreasing towards a same given operating value V_{A}.

According to the step e.4) of the determination procedure DP, both the input channels CH₁, CH₂ are determined as parallel input channels.

The determination of the configuration status of the input channels of the inverter 100 is completed.

### EXAMPLE #3

The inverter 100 is supposed to have three input channels CH₁, CH₂, CH₃ electrically connected with corresponding DC sources S₁, S₂, S₃ and corresponding power converters C₁, C₂, C₃ that are supposed to be initially deactivated.

According to the step a) of the method 1, the input channel CH₁ is selected as a reference input channel. As a consequence, the input channels CH₂, CH₃ represent the remaining input channels of the inverter 100 as defined above.

According to the step b) of the method 1, at a given check instant t₁, the power converter C₁ corresponding to the reference input channel CH₁ is activated whereas the power converters C₂, C₃ operatively associated to the remaining input channels CH₂, CH₃, are maintained activated.

According to the steps c)-d) of the method 1, detection data D related to the input voltages V₁, V₂, V₃ of the input channels CH₁, CH₂, CH₃ are acquired and compared.

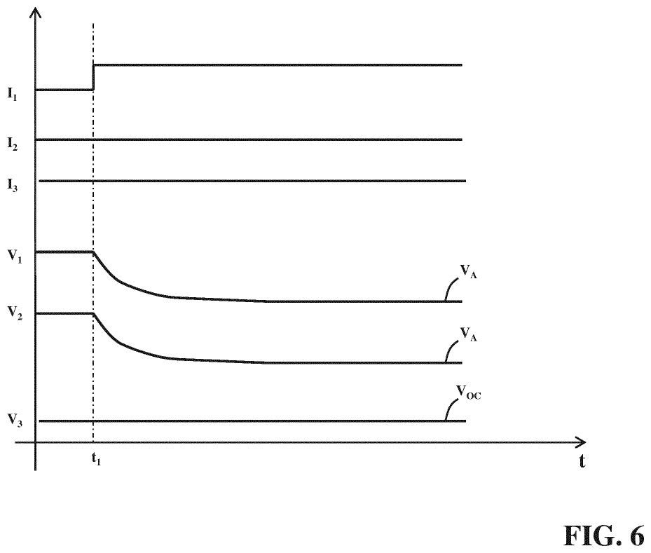

As it is possible to observe from FIG. 6, following the activation of the power converter C₁ at the check instant t₁, the input voltage V₂ of the remaining input channel CH₂ behaves as the input voltage V₁ of the reference input channel CH₁, i.e. it starts decreasing towards a same given operating value V_{A}. Instead, the input voltage V₃ of the remaining input channel CH₃ stably remains at its no-load value V_{OC}.

According to the steps e.4) and e.5) of the determination procedure DP, the input channels CH₁, CH₂ are determined as parallel input channels whereas the input channel CH₃ is determined as an independent input channel.

The determination of the configuration status of the input channels of the inverter 100 is completed.

### EXAMPLE #4

In this example, the inverter 100 is arranged as in the example #3, i.e. it comprises three input channels CH₁, CH₂, CH₃.

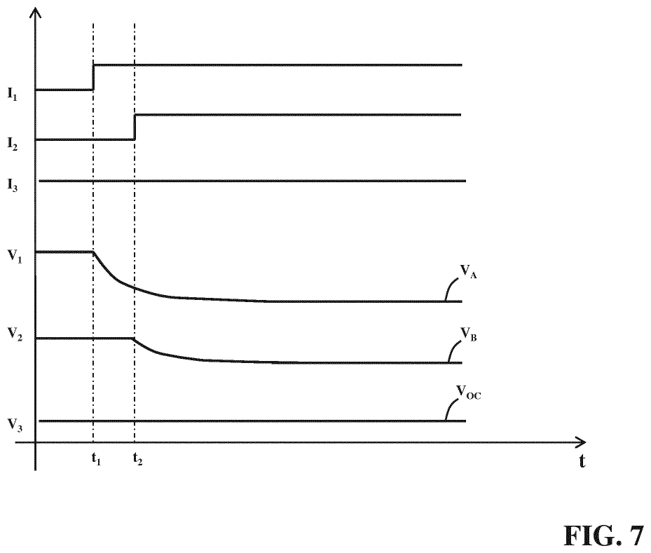

As it is possible to observe from FIG. 7, differently from the previous example, following the activation of the power converter C₁ at the check instant t₁, only the input voltage V₁ of the reference input channel CH₁ starts decreasing towards a given operating value V_{A}. Instead, the input voltages V₂, V₃ of the remaining input channels CH₂, CH₃ stably remain at their no-load values V_{OC}.

According to the step e.1) of the method 1, the input channel CH₁ is determined as an independent input channel.

However, the determination of the configuration status of the input channels of the inverter 100 is not completed at this level of the determination procedure.

In fact, no determination can be taken for the channels CH₂, CH₃ as their input voltages V₂, V₃ stably remain at their no-load values V_{OC} following the activation of the power converter C₁ at the check instant t₁.

According to the step e.3) of the determination procedure DP, the steps a)-e) of the method 1 are recursively repeated for the input channels CH₂, CH₃ only.

According to the step a) of the method 1, the input channel CH₂ is selected as new reference input channel. Accordingly, the input channel CH₃ represents the new remaining channel of the inverter 100 as defined above.

According to the step b) of the method 1, at a given check instant t₂, the power converter C₂ corresponding to the new reference input channel CH₂ is activated whereas the power converter C₃ operatively associated to the new remaining input channel CH₃ is maintained deactivated.

According to the steps c)-d) of the method 1, detection data D related to the input voltages V₂, V₃ of the input channels CH₂, CH₃ are acquired and compared.

As it is possible to observe from FIG. 7, following the activation of the power converter C₂ at the check instant t₂, the input voltage V₂ of the reference input channel CH₂ starts decreasing towards a given operating value V_{B}. This latter value depends on the current regulation performed the power converter C₂. Instead, the input voltage V₃ of the remaining input channel CH₃ stably remains at its no-load value V_{OC}.

According to the steps e.1)-e.2) of the determination procedure DP, both the input channels CH₂, CH₃ are determined as independent input channels.

The determination of the configuration status of the input channels of the inverter 100 is now completed.

### EXAMPLE #5

The inverter 100 is supposed to have six input channels CH₁, CH₂, CH₃, CH₄, CH₅, CH₆ electrically connected with corresponding DC sources S₁, S₂, S₃, S₄, S₅, S₆ and corresponding power converters C₁, C₂, C₃, C₄, C₅, C₆ that are supposed to be initially deactivated.

According to the step a) of the method 1, the input channel CH₁ is selected as a reference input channel. The input channels CH₂, CH₃, CH₄, CH₅, CH₆ represent the remaining input channels of the inverter 100 as defined above.

According to the step b) of the method 1, at a given check instant t₁, the power converter C₁ corresponding to the reference input channel CH₁ is activated whereas the power converters C₂, C₃, C₄, C₅, C₆, operatively associated to the remaining input channels CH₂, CH₃, CH₄, CH₅, CH₆, are maintained deactivated.

According to the steps c)-d) of the method 1, detection data D related to the input voltages V₁, V₂, V₃, V₄, V₅, V₆ of the input channels are acquired and are compared.

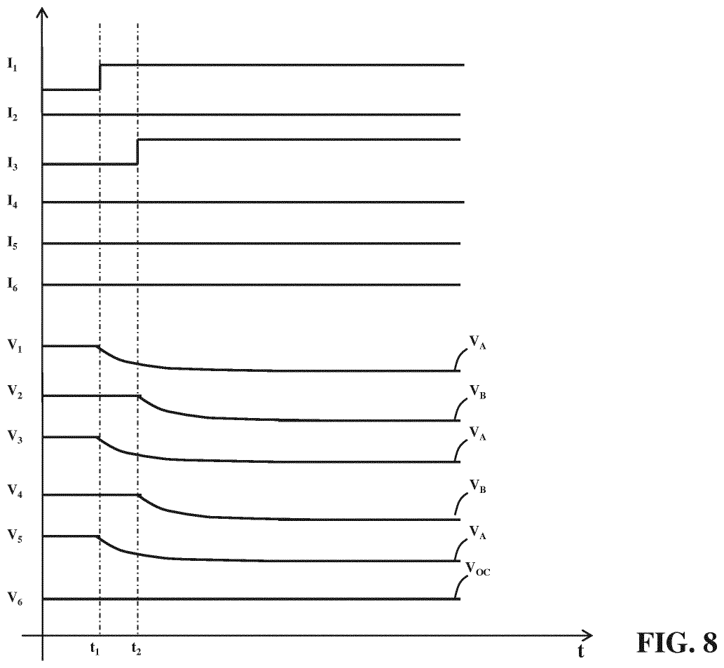

As it is possible to observe from FIG. 8, following the activation of the power converter C₁ at the check instant t₁, the input voltages V₃, V₅ of the remaining input channels CH₃, CH₅ behave as the input voltage V₁ of the reference input channel CH₁, i.e. they start decreasing towards a same given operating value V_{A}. Instead, the input voltages V₂, V₄, V₆ of the remaining input channels CH₂, CH₄, CH₆ stably remain at their no-load values V_{OC}.

According to the steps e.4) and e.5) of the determination procedure DP, the input channels CH₁, CH₃, CH₅ are determined as parallel channels.

However, the determination of the configuration status of the input channels of the inverter 100 is not completed at this level of the determination procedure.

In fact, no determination can be taken for the channels CH₂, CH₄, CH₆ as their input voltages V₂, V₄, V₆ stably remain at their no-load values V_{OC} following the activation of the power converter C₁ at the check instant t₁.

According to the step e.6) of the method 1, the steps a)-e) of the method are recursively repeated for the input channels CH₂, CH₄, CH₆ only.

According to the step a) of the method 1, the input channel CH₂ is selected as new reference input channel. Accordingly, the input channels CH₄, CH₆ represent the new remaining channels of the photovoltaic inverter as defined above.

According to the step b) of the method 1, at a given check instant t₂, the power converter C₂ corresponding to the new reference input channel CH₂ is activated the power converters C₃, C₆, operatively associated to the new remaining input channels CH₄, CH₆, are maintained deactivated.

According to the steps c)-d) of the method 1, detection data D related to the input voltages V₂, V₄, V₆ of the input channels CH₂, CH₄, CH₆ are acquired and compared.

As it is possible to observe from FIG. 8, following the activation of the power converter C₂ at the check instant t₂, the input voltage V₄ of the new remaining input channel CH₄ behaves as the input voltage V₂ of the new reference input channel CH₂, i.e. it starts decreasing towards a given operating value V_{B}. Instead, the input voltage V₆ of the new remaining input channel CH₆ stably remains at its no-load value V_{OC}.

According to the steps e.4) and e.5) of the determination procedure DP, the input channels CH₂, CH₄ are determined as parallel input channels whereas the input channel CH₆ is determined as an independent input channel.

The determination of the configuration status of the input channels of the inverter 100 is now completed.

### EXAMPLE #6

In this example, the inverter 100 is arranged as in the example #1, i.e. it comprises two input channels CH₁, CH₂.

According to the step a) of the method 1, the input channel CH₁ is selected as a reference input channel. As a consequence, the input channel CH₂ represents the remaining input channel of the inverter 100 as defined above.

According to the step b) of the method 1, at a given check instant t₁, the power converters C1, C2 are controlled in such a way that the power converter C₁ corresponding to the reference input channel CH₁ is fed with a current I₁ higher than a given threshold I_{TH} and the power converter C₂ operatively associated to the remaining input channel CH₂ is fed with a current I₂ lower than a given threshold I_{TH}.

To this aim, as shown in FIG. 10, the power converters C1, C2 are controlled in such a way that the power converter C₁ corresponding to the reference input channel CH₁ is fed with a current I₁ having a higher growth rate and the power converter C₂ operatively associated to the remaining input channel CH₂ is fed with a current I₂ having lower than a lower growth rate.

According to the steps c)-d) of the method 1, detection data D related to the input voltages V₁, V₂ of the input channels CH₁, CH₂ are acquired and compared.

As it is possible to observe in FIG. 9, following the activation of the power converter C₁ at the check instant t₁, the input voltage V₁ of the reference input channel CH₁ starts naturally decreasing towards a given operating value V_{A}. This latter value depends on the current regulation performed by the power converter C₁ (FIG. 10). Instead, the input voltage V₂ of the remaining input channel CH₂ decrease to a voltage V_{Q} higher than V_{A}.

According to the steps e.1)-e.2) of the determination procedure DP, both the input channels CH₁, CH₂ are determined as independent input channels.

The determination of the configuration status of the input channels of the inverter 100 is completed.

This example clearly shows that the determination of the configuration status of the input channels can be suitably carried out also in the general case in which the power converters C₁, . . . , C_{N} are controlled in such a way the input current flowing along the reference input channel is set higher than the current threshold I_{TH} and the input currents flowing along the remaining input channels are set lower than said current threshold.

In this respect, further examples similar to examples #2 to #5 may be easily provided by simply considering different current profiles for the input currents I₁, . . . , I_{N} flowing along the input channels CH₁, . . . , CH_{N}.

The above examples clearly show how the input channel configuration of the inverter 100 can be determined based on the detection data D by observing behavior of the input voltages V₁, . . . , V_{N} of the input channels CH₁, . . . , CH_{N} following a selective current feeding of the input channels CH₁, . . . , CH_{N}, e.g. obtained through a selective activation and deactivation of the power converters C₁, . . . , C_{N} corresponding to said input channels or by controlling said power converters in such a way that said input channels are fed with currents having selected profiles.

According to a preferred embodiment of the invention, the method 1 comprises the step f) of storing information I indicative of the configuration status determined for the input channels CH₁, . . . , CH_{N} of the inverter 100.

Preferably, the step f) of the method 1 is carried out concurrently with the execution of the step e), for example each time the configuration status of an input channel is taken into consideration during the above-mentioned determination procedure.

The configuration information I attributed to the input channels CH₁, . . . , CH_{N} during the execution of the determination procedure DP is conveniently formed by suitable sets of bits (variable values) stored in a memory.

As an example, each input channel may be labeled as “independent”, “parallel” or “undetermined” depending on the determination taken on its configuration status or depending on the level reached in the decision process implemented by the determination procedure DP.

Of course, when the execution of the step e) is completed, all the input channels of the inverter 100 are expected to be labeled as “independent” or “parallel”.

The stored configuration information I is used by the control means 140 for controlling the operation of the inverter 100, e.g. for carrying out a MMPT regulation of the electric power generated and transmitted to the electric power distribution grid.

Conveniently, in its practical implementation, the method 1 is particularly adapted for being executed by data processing resources residing in the inverter 100.

Preferably, the method 1 is executed by the above-mentioned data-processing resources 160 of the control means 140 of the inverter 100.

The method, according to the present invention, provides several advantages with respect to the state of the art.

The method, according to the invention, allows automatically determining with high levels of accuracy the configuration status of the input channels of a photovoltaic inverter.

The photovoltaic inverter can thus behave as a “plug & play” apparatus capable of storing the required configuration information related to the configuration status of the input channels without the intervention of an external operator, simply carrying out the method of the invention at each power-up.

This feature allows achieving a remarkable reduction of the commissioning time and costs to put the photovoltaic inverter in condition for properly operating.

Additionally, an improvement of the overall control functionalities of the photovoltaic inverter can be achieved as human errors in setting the above-mentioned configuration information are avoided.

The method, according to the invention, is characterized by a high level of flexibility in its practical implementation. Thus, it may be successfully adopted in multi-channels photovoltaic inverters of different types, e.g. having different numbers of input channels.

The method, according to the invention, is of relatively easy implementation at industrial level. As an example, it may be easily carried out by processing devices on board the photovoltaic inverter, such as microcontrollers or DSPs.

1. A method for detecting an input channel configuration of a multi-channel inverter having a plurality of input channels, each input channel being electrically connected with a corresponding power converter and, upon an operative installation of said multi-channel inverter, being operatively associated to a DC electric power source, the method comprises
a) selecting a reference input channel among said input channels;
b) controlling said power converters to allow an input current higher than a current threshold to flow along said reference input channel and to allow input currents lower than said current threshold to flow along one or more remaining input channels different from said reference input channel;
c) acquiring detection data indicative of input voltages of said input channels;
d) performing a comparison between the input voltages of said input channels;
e) executing a determination procedure to determine a configuration status of said input channels based on a behavior of the input voltages of said remaining input channels with respect to the input voltage of said reference channel.

2. The method, according to claim 1, wherein said controlling said power converters comprises activating the power converter corresponding to said reference input channel and deactivating or maintaining deactivated the power converters corresponding to said remaining input channels.

3. The method, according to claim 2, wherein said performing a comparison between the input voltages of said input channels comprises checking whether the input voltages of said remaining input channels behave as the input voltage of said reference input channel.

4. The method, according to claim 3, wherein said determination procedure further comprises:
e.1) if the input voltages of said remaining input channels do not decrease as the input voltage at said reference input channel, determining that said reference input channel is an independent input channel.

5. The method, according to claim 4, wherein said determination procedure further comprises:
e.2) if there is a single remaining input channel, determining that said remaining input channel is an independent input channel; or
e.3) if there is a plurality of remaining input channels, repeating said acts a), b), c), d), e) for said remaining input channels.

6. The method, according to claim 3, wherein said determination procedure further comprises:
e.4) if the input voltages of one or more first remaining input channels decrease as the input voltage at said reference input channel, determining that said reference input channel and said one or more first remaining input channels are parallel input channels.

7. The method, according to claim 6, wherein if the input voltages of one or more second remaining input channels, do not decrease as the input voltage of said reference input channel said determination procedure comprises:
e.5) if said second remaining channels include a single second remaining input channel, determining that said remaining input channel is an independent input channel; or
e.6) if said second remaining channels include a plurality of second remaining input channels, repeating said acts a), b), c), d), e) for said second remaining input channels.

8. The method, according to claim 7, further comprising storing configuration information indicative of the configuration status determined for said input channels.

9. A multi-channel inverter electrically connectable with a DC electric system and an AC electric system comprising data processing resources configured to execute instructions to detect an input channel configuration of the multi-channel inverter having a plurality of input channels, each input channel being electrically connected with a corresponding power converter, and execute instructions that comprise:
select a reference input channel among said input channels;
control said power converters to allow an input current higher than a current threshold to flow along said reference input channel and to allow input currents lower than said current threshold to flow along one or more remaining input channels different from said reference input channel;
acquire detection data indicative of input voltages of said input channels;
perform a comparison between the input voltages of said input channels;
execute a determination procedure to determine a configuration status of said input channels based on a behavior of the input voltages of said remaining input channels with respect to the input voltage of said reference channel.

10. (canceled)

11. The multi-channel inverter, according to claim 9, wherein it is a photovoltaic inverter.

12. The method, according to claim 1, wherein said performing a comparison between the input voltages of said input channels comprises checking whether the input voltages of said remaining input channels behave as the input voltage of said reference input channel.

13. The method, according to claim 12, wherein said determination procedure further-comprises:
e.1) if the input voltages of said remaining input channels do not decrease as the input voltage at said reference input channel, determining that said reference input channel is an independent input channel.

14. The method, according to claim 13, wherein said determination procedure further comprises:
e.2) if there is a single remaining input channel, determining that said remaining input channel is an independent input channel; or
e.3) if there is a plurality of remaining input channels, repeating said acts a), b), c), d), e) for said remaining input channels.

15. The method, according to claim 12, wherein said determination procedure further comprises:
e.4) if the input voltages of one or more first remaining input channels decrease as the input voltage at said reference input channel, determining that said reference input channel and said one or more first remaining input channels are parallel input channels.

16. The method, according to claim 15, wherein if the input voltages of one or more second remaining input channels, do not decrease as the input voltage of said reference input channel said determination procedure comprises:
e.5) if said second remaining channels include a single second remaining input channel, determining that said remaining input channel is an independent input channel; or
e.6) if said second remaining channels include a plurality of second remaining input channels, repeating said acts a), b), c), d), e) for said second remaining input channels.

17. The method, according to claim 16, further comprising storing configuration information indicative of the configuration status determined for said input channels.

18. The method, according to claim 1, further comprising storing configuration information indicative of the configuration status determined for said input channels.

19. The method, according to claim 2, further comprising storing configuration information indicative of the configuration status determined for said input channels.

20. The method, according to claim 3, further comprising storing configuration information indicative of the configuration status determined for said input channels.
